(19) United States
(12) Patent Application Publication
(10) Pub. No.: US 2025/0118669 A1
(43) Pub. Date: Apr. 10, 2025

(54) SEMICONDUCTOR DEVICES

(71) Applicant: SAMSUNG ELECTRONICS CO., LTD., Suwon-si (KR)

(72) Inventors: EUI BOK LEE, Suwon-si (KR); RAKHWAN KIM, Suwon-si (KR)

(21) Appl. No.: 18/630,670

(22) Filed: Apr. 9, 2024

(30) Foreign Application Priority Data
Oct. 6, 2023 (KR) 10-2023-0133537

(51) Int. Cl. H01L 23/528; H01L 29/423

(52) U.S. Cl. CPC H01L 23/5283; H10D 30/6735

(57) ABSTRACT

A semiconductor device comprising: first conductive lines spaced apart from each other; and a conductive structure in contact with upper surfaces of the first conductive lines, wherein the conductive structure includes a lower portion of the conductive structure and an upper portion of the conductive structure, wherein the lower portion of the conductive structure is in contact with the upper surfaces of the first conductive lines, wherein the upper portion of the conductive structure is on the lower portion of the conductive structure, wherein a width of the lower portion of the conductive structure decreases as a distance between the lower portion of the conductive structure and the upper surfaces of the first conductive lines decreases, and wherein a width of the upper portion of the conductive structure increases as a distance between the upper portion of the conductive structures and the upper surfaces of the first conductive lines decreases.

### REFERENCE TO RELATED APPLICATIONS

This U.S. non-provisional patent application claims priority under 35 U.S.C. § 119 to Korean Patent Application No. 10-2023-0133537, filed on Oct. 6, 2023, in the Korean Intellectual Property Office, the entire contents of which are hereby incorporated by reference.

### BACKGROUND OF THE INVENTION

The present disclosure relates to semiconductor devices, and in particular, to semiconductor devices including a conductive structure.

A semiconductor device may include an integrated circuit, including metal-oxide-semiconductor field-effect transistors (MOSFETs). To meet an increasing demand for semiconductor devices with a small pattern size and a reduced design rule, the MOSFETs are being scaled down. The scale-down of the MOSFETs may lead to deterioration in operational properties of semiconductor devices. A variety of studies are being conducted to overcome technical limitations associated with the scale-down of semiconductor devices and to realize high-performance semiconductor devices.

### SUMMARY OF THE INVENTION

Some embodiments of the inventive concept may provide semiconductor devices with improved electrical and reliability characteristics.

According to an embodiment of the inventive concept, a semiconductor device may include first conductive lines that are spaced apart from each other; and a conductive structure that is in contact with upper surfaces of the first conductive lines, wherein the conductive structure includes a lower portion of the conductive structure and an upper portion of the conductive structure, wherein the lower portion of the conductive structure is in contact with the upper surfaces of the first conductive lines, wherein the upper portion of the conductive structure is on the lower portion of the conductive structure, wherein a width of the lower portion of the conductive structure decreases as a distance between the lower portion of the conductive structure and the upper surfaces of the first conductive lines decreases, and wherein a width of the upper portion of the conductive structure increases as a distance between the upper portion of the conductive structures and the upper surfaces of the first conductive lines decreases.

According to an embodiment of the inventive concept, a first interlayer insulating layer; an etch stop layer on the first interlayer insulating layer; a second interlayer insulating layer on the etch stop layer; a third interlayer insulating layer on the second interlayer insulating layer; first conductive lines that are spaced apart from each other and extend in the first interlayer insulating layer; and a conductive structure that extends in the second interlayer insulating layer, the third interlayer insulating layer, and the etch stop layer and is in contact with upper surfaces of the first conductive lines, wherein the first interlayer insulating layer includes an intervening portion between the first conductive lines, wherein the upper surfaces of the first conductive lines are coplanar with an upper surface of the intervening portion, and wherein a lower surface of the conductive structure is in contact with the upper surfaces of the first conductive lines and the upper surface of the intervening portion.

According to an embodiment of the inventive concept, a substrate that includes an active pattern; source/drain patterns on the active pattern; a channel structure between the source/drain patterns; a gate electrode that overlaps with the channel structure; an active contact on each of the source/drain patterns; a cover insulating layer on the active contact; a first etch stop layer on the cover insulating layer; a first interlayer insulating layer on the first etch stop layer; first conductive lines that are spaced apart from each other and extend in the first etch stop layer and the first interlayer insulating layer; a second etch stop layer on the first interlayer insulating layer and the first conductive lines; a second interlayer insulating layer on the second etch stop layer; a third interlayer insulating layer on the second interlayer insulating layer; and a conductive structure that is in contact with upper surfaces of the first conductive lines and extends in the second etch stop layer, the second interlayer insulating layer, and the third interlayer insulating layer, wherein each of the first conductive lines is electrically connected to the active contact or the gate electrode, wherein the conductive structure incudes a barrier layer and a conductive layer on the barrier layer, wherein an outer side surface of the barrier layer is in contact with the second interlayer insulating layer, and wherein an outer side surface of the conductive layer is in contact with the third interlayer insulating layer.

According to an embodiment of the inventive concept, a method of fabricating a semiconductor device may include forming a first interlayer insulating layer; forming first conductive lines that are spaced apart from each other and extend in the first interlayer insulating layer; forming an etch stop layer on the first interlayer insulating layer and the first conductive lines; forming a second interlayer insulating layer on the etch stop layer; etching the second interlayer insulating layer to form a first opening; etching the etch stop layer through the first opening to form a second opening, wherein the second opening exposes upper surfaces of the first conductive lines; forming a preliminary barrier layer to be in contact with the upper surfaces of the first conductive lines, a side surface of the etch stop layer, and side and upper surfaces of the second interlayer insulating layer; forming a preliminary conductive layer on the preliminary barrier layer; forming a mask layer on the preliminary conductive layer; and etching the preliminary conductive layer and the preliminary barrier layer using the mask layer as an etch mask.

### BRIEF DESCRIPTION OF THE DRAWINGS

FIGS. 1 to 3 are simplified diagrams illustrating logic cells of a semiconductor device, according to some embodiments of the inventive concept.

FIG. 4A is a plan view illustrating a semiconductor device according to some embodiments of the inventive concept.

FIG. 4B is a sectional view taken along a line A1-A1′ of FIG. 4A.

FIG. 4C is a sectional view taken along a line B1-B1′ of FIG. 4A.

FIG. 4D is an enlarged view illustrating a portion E1 of FIG. 4B.

FIG. 4E is an enlarged view illustrating a portion E2 of FIG. 4C.

FIGS. 5, 6, 7, 8, 9, and 10 are sectional views illustrating a method of fabricating the semiconductor device of FIGS. 4A to 4E.

FIG. 11 is an enlarged sectional view illustrating a semiconductor device according to some embodiments of the inventive concept.

FIG. 12 is an enlarged sectional view illustrating a semiconductor device according to some embodiments of the inventive concept.

FIG. 13 is an enlarged sectional view illustrating a semiconductor device according to some embodiments of the inventive concept.

FIG. 14 is an enlarged sectional view illustrating a semiconductor device according to some embodiments of the inventive concept.

FIG. 15 is an enlarged sectional view illustrating a semiconductor device according to some embodiments of the inventive concept.

FIG. 16 is a sectional view illustrating a semiconductor device according to some embodiments of the inventive concept.

### DETAILED DESCRIPTION

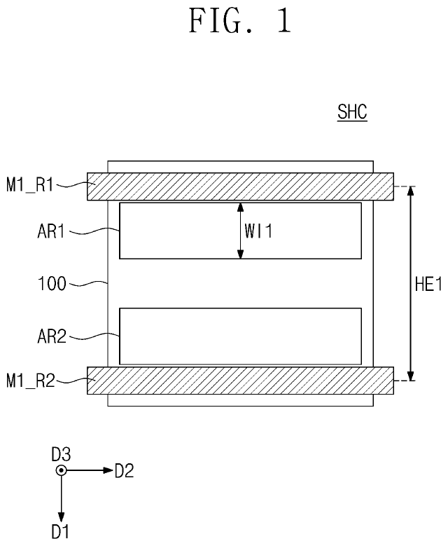

FIGS. 1 to 3 are simplified diagrams illustrating logic cells of a semiconductor device, according to some embodiments of the inventive concept.

Referring to FIG. 1, a single height cell SHC may be provided. A first power line M1_R1 and a second power line M1_R2 may be provided on a substrate 100. The first power line M1_R1 may be a conduction path, to which a source voltage VSS is provided. In some embodiments, the first power line M1_R1 may be a conduction path, to which a ground voltage is provided. The second power line M1_R2 may be a conduction path, to which the drain voltage VDD is provided. In some embodiments, the second power line M1_R2 may be a conduction path, to which a power voltage is provided.

The single height cell SHC may be defined between (a portion (a central portion in a first direction D1) of) the first power line M1_R1 and (a portion (a central portion in the first direction D1) of) the second power line M1_R2. The single height cell SHC may include one first active region AR1 and one second active region AR2. One of the first and second active regions AR1 and AR2 may be a PMOSFET region, and the other of the first and second active regions AR1 and AR2 may be an NMOSFET region. The single height cell SHC may have a CMOS structure provided between (a portion (a central portion in the first direction D1) of) the first power line M1_R1 and (a portion (a central portion in the first direction D1) of) the second power line M1_R2.

Each of the first and second active regions AR1 and AR2 may have a first width WII in the first direction D1. A length of the single height cell SHC in the first direction D1 may be defined as a first height HE1. The first height HE1 may be (substantially) equal to a distance (e.g., a pitch) between (a portion (a central portion in the first direction D1) of) the first power line M1_R1 and (a portion (a central portion in the first direction D1) of) the second power line M1_R2.

The single height cell SHC may constitute a single logic cell. In the present specification, the logic cell may mean a logic device (e.g., AND, OR, XOR, XNOR, inverter, and so forth), which is configured to execute a specific function. The logic cell may include transistors constituting the logic device and interconnection lines connecting (e.g., electrically connecting) the transistors to each other. It will be understood that when an element or layer is referred to as being “connected to”, or “coupled to”, another element or layer, it may be directly on, connected to, or coupled to the other element or layer, or one or more intervening elements or layers may be present. In contrast, when an element is referred to as being “directly coupled,” “directly connected,” or “directly responsive” to, or “directly on,” another element, there are no intervening elements present. In addition, “electrical connection” conceptually includes a physical connection and a physical disconnection.

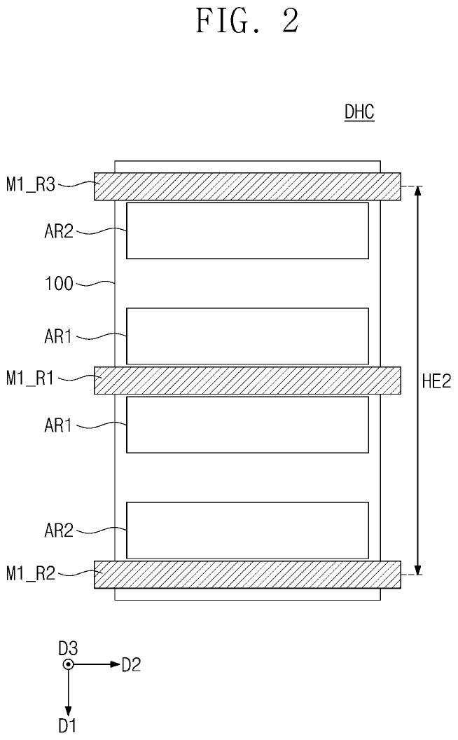

Referring to FIG. 2, a double height cell DHC may be provided. In detail, a first power line M1_R1, a second power line M1_R2, and a third power line M1_R3 may be provided on the substrate 100. The first power line M1_R1 may be disposed between the second power line M1_R2 and the third power line M1_R3 (in the first direction D1). The third power line M1_R3 may be a conduction path, to which the source voltage VSS is provided.

The double height cell DHC may be defined between (a (central) portion in the first direction D1 of) the second power line M1_R2 and (a (central) portion in the first direction D1 of) the third power line M1_R3. The double height cell DHC may include two first active regions AR1 and two second active regions AR2.

One of the two second active regions AR2 may be adjacent to the second power line M1_R2. The other of the two second active regions AR2 may be adjacent to the third power line M1_R3. The two (or the pair of) first active regions AR1 may be adjacent to the first power line M1_R1. When viewed in a plan view, the first power line M1_R1 may be disposed between the pair of the first active regions AR1 (in the first direction D1).

A length of the double height cell DHC in the first direction D1 may be defined as a second height HE2. The second height HE2 may be about two times the first height HE1 of FIG. 1. The pair of the first active regions AR1 of the double height cell DHC may be combined to serve as a single active region.

The double height cell DHC shown in FIG. 2 may be defined as a multi-height cell. In some embodiments, the multi-height cell may include a triple height cell whose cell height is about three times that of the single height cell SHC.

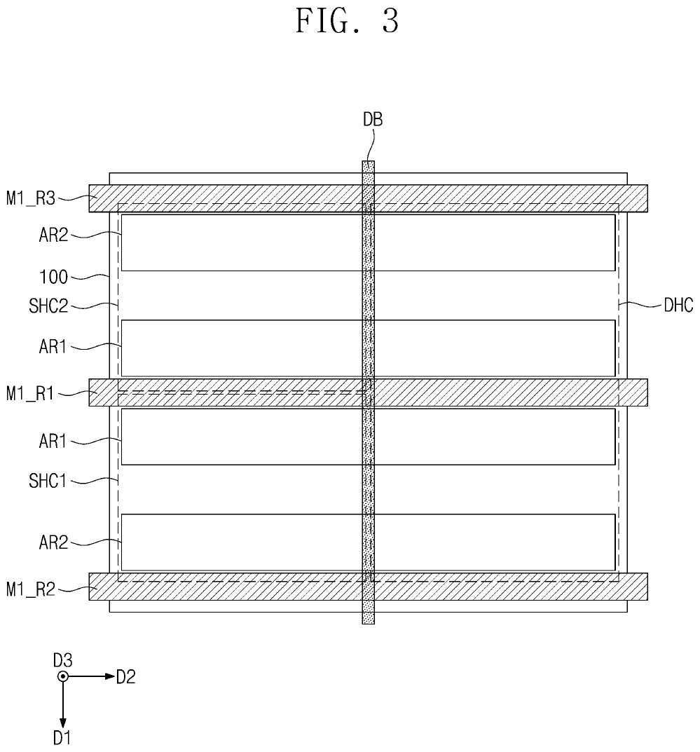

Referring to FIG. 3, a first single height cell SHC1, a second single height cell SHC2, and a double height cell DHC may be two-dimensionally disposed on the substrate 100. The first single height cell SHC1 may be disposed between the first and second power lines M1_R1 and M1_R2. The second single height cell SHC2 may be disposed between the first and third power lines M1_R1 and M1_R3. The second single height cell SHC2 may be adjacent to the first single height cell SHC1 in the first direction D1.

The double height cell DHC may be disposed between the second and third power lines M1_R2 and M1_R3. The double height cell DHC may be adjacent to the first and second single height cells SHC1 and SHC2 in a second direction D2.

A division structure DB may be provided between the first single height cell SHC1 and the double height cell DHC and between the second single height cell SHC2 and the double height cell DHC. The active region (e.g., the first active region AR1 and/or the second active region AR2) of the double height cell DHC may be electrically separated from the active region (e.g., the first active region AR1 and/or the second active region AR2) of each of the first and second single height cells SHC1 and SHC2 by the division structure DB. As used herein, the term “and/or” includes any and all combinations of one or more of the associated listed items. Expressions such as “at least one of,” when preceding a list of elements, modify the entire list of elements and do not modify the individual elements of the list.

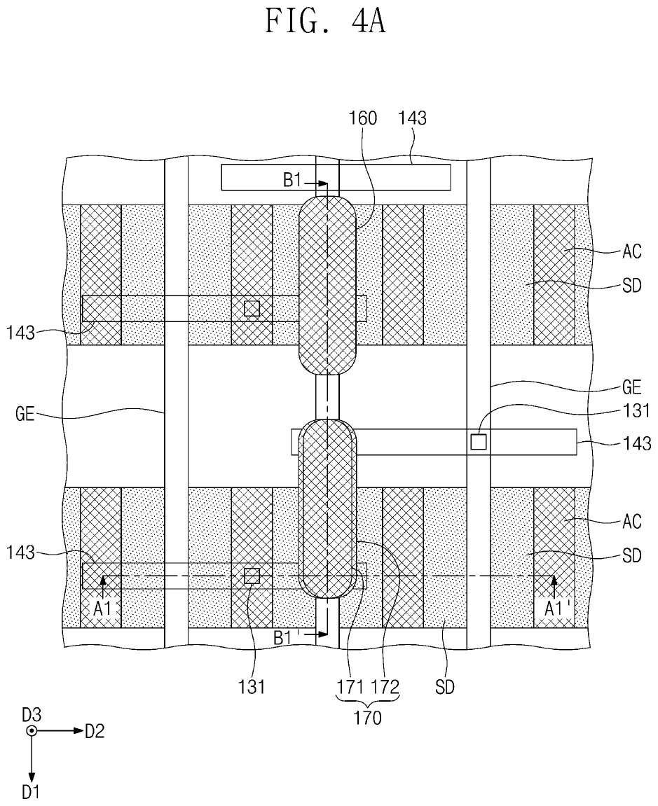

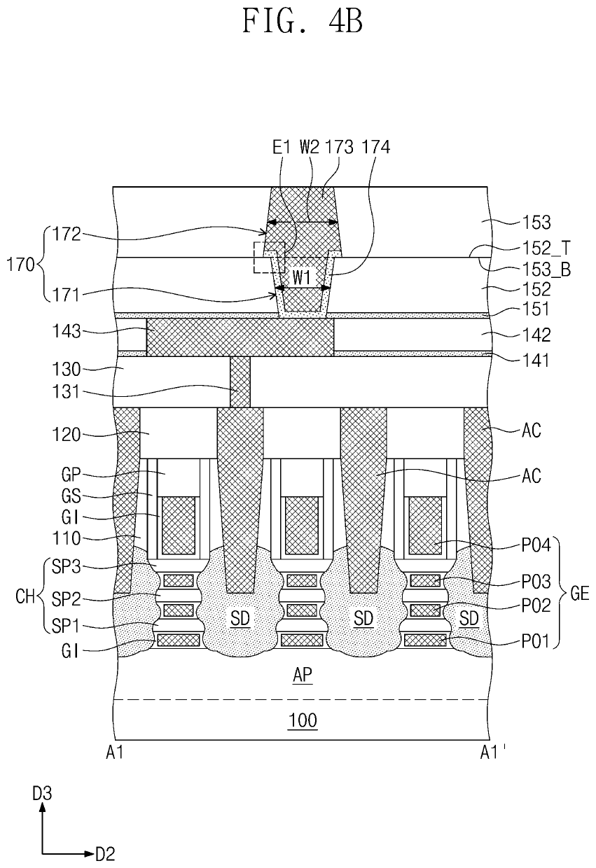

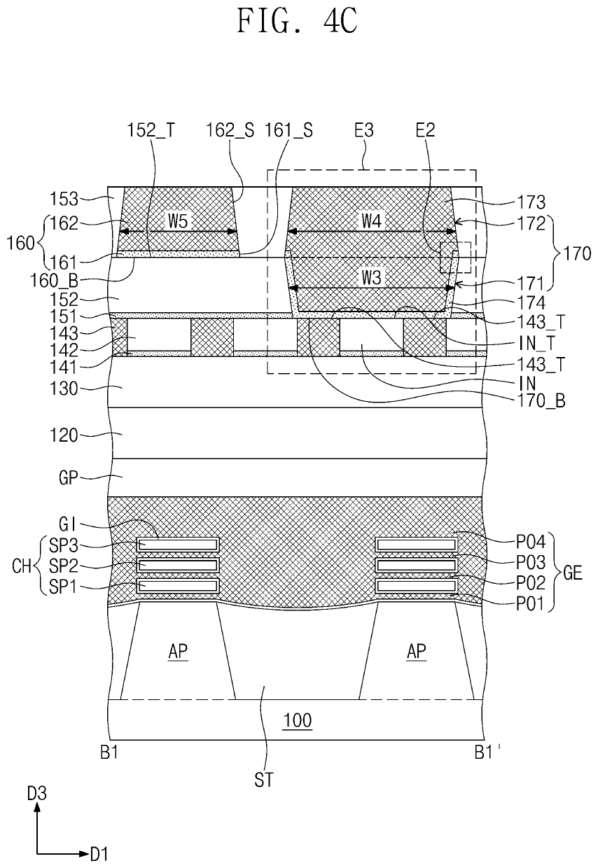

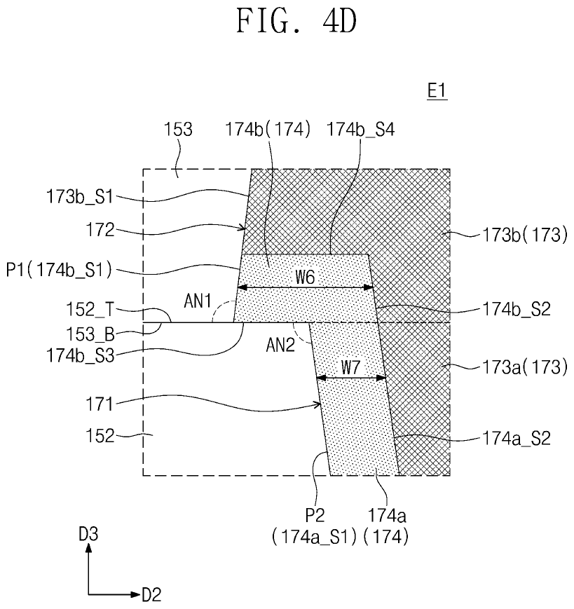

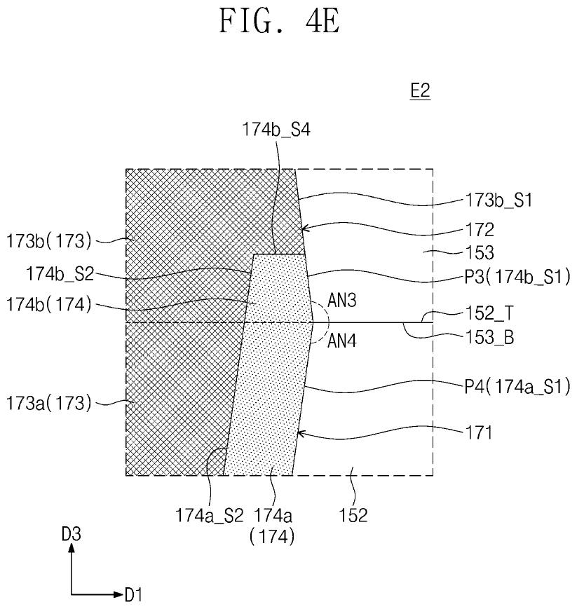

FIG. 4A is a plan view illustrating a semiconductor device according to some embodiments of the inventive concept. FIG. 4B is a sectional view taken along a line A1-A1′ of FIG. 4A. FIG. 4C is a sectional view taken along a line B1-B1′ of FIG. 4A. FIG. 4D is an enlarged view illustrating a portion E1 of FIG. 4B. FIG. 4E is an enlarged view illustrating a portion E2 of FIG. 4C.

Referring to FIGS. 4A to 4C, the semiconductor device may include the substrate 100. The single height cell SHC may be provided on the substrate 100. A logic cell may be disposed on the single height cell SHC. In some embodiments, the substrate 100 may include (e.g., may be) a semiconductor substrate. As an example, the substrate 100 may be formed of or include silicon, germanium, silicon-germanium, GaP, and/or GaAs. In some embodiments, the substrate 100 may include (e.g., may be) an insulating substrate, a silicon-on-insulator (SOI) substrate, and/or a germanium-on-insulator (GOI) substrate. The substrate 100 may be a plate-shaped structure which is extended in the first and second directions D1 and D2. The first and second directions D1 and D2 may not be parallel to each other. The first and second directions D1 and D2 may be parallel with an upper surface of the substrate 100. The first and second directions D1 and D2 may be horizontal directions that intersect (e.g., that are orthogonal to) each other.

The substrate 100 may include active patterns AP. The active patterns AP may be defined by a trench (which will be at least partially filled with a device isolation layer ST described below) on the substrate 100. For example, the active patterns AP may be adjacent to the trench (or the device isolation layer ST). The active patterns AP may be extended in the second direction D2. The active patterns AP may be portions of the substrate 100 that are formed to protrude in a third direction D3. The third direction may be perpendicular to the upper surface of the substrate 100. The third direction D3 may not be parallel to the first and second directions D1 and D2. The third direction D3 may be a vertical direction that is orthogonal to the first and second directions D1 and D2.

A device isolation layer ST may be provided on the substrate 100. The device isolation layer ST may (at least partially) fill the trench on the substrate 100. The device isolation layer ST may include an insulating material. For example, the device isolation layer ST may be formed of or include at least one of oxide materials.

Source/drain patterns SD may be provided on the active pattern AP. In some embodiments, the source/drain patterns SD may be arranged (e.g., may be spaced apart from each other) on the active pattern AP in the second direction D2.

The source/drain patterns SD may be epitaxial patterns, which are formed by a selective epitaxial growth (SEG) process. The source/drain patterns SD may include a semiconductor material. In some embodiments, the source/drain patterns SD may be formed of or include silicon (Si), silicon-germanium (SiGe), and/or germanium (Ge). In some embodiments, the source/drain pattern SD, which is connected (e.g., electrically connected) to one of the active patterns AP, may be doped with p-type impurities to have a p-type conductivity type, and the source/drain pattern SD, which is connected (e.g., electrically connected) to the other of the active patterns AP, may be doped with n-type impurities to have an n-type conductivity type.

A channel structures CH may be provided. The channel structures CH may be provided between the source/drain patterns SD, which are adjacent to each other. The channel structures CH may be overlapped with the active pattern AP in the third direction D3. The channel structures CH, which are overlapped with each active pattern AP in the third direction D3, may be arranged (e.g., may be spaced apart from each other) in the second direction D2. As used herein, “an element A overlapping an element B in a direction X” (or similar language) means that there is at least one line that extends in the direction X and intersects both the elements A and B.

Each of the channel structures CH may include a first semiconductor pattern SP1, a second semiconductor pattern SP2, and a third semiconductor pattern SP3, which are spaced apart from each other in the third direction D3. The first, second, and third semiconductor patterns SP1, SP2, and SP3 may be overlapped with each other in the third direction D3. The first, second, and third semiconductor patterns SP1, SP2, and SP3 may be formed of or include a semiconductor material. As an example, the first, second, and third semiconductor patterns SP1, SP2, and SP3 may be formed of or include silicon.

The number of the semiconductor patterns SP1, SP2, and SP3 in each channel structure CH is not limited to the illustrated example. In some embodiments, the number of the semiconductor patterns SP1, SP2, and SP3 in each channel structure CH may be less than or equal to two or may be greater than or equal to four.

Gate electrodes GE may be provided to extend in the first direction D1. The gate electrode GE may be provided to cross at least one of the active patterns AP. The gate electrode GE may be provided to cross at least one of the channel structures CH. The gate electrode GE may be overlapped with the channel structure CH in the third direction D3.

The gate electrode GE may include a first electrode portion PO1 between the active pattern AP and the first semiconductor pattern SP1, a second electrode portion PO2 between the first and second semiconductor patterns SP1 and SP2, a third electrode portion PO3 between the second and third semiconductor patterns SP2 and SP3, and a fourth electrode portion PO4 on the third semiconductor pattern SP3. The gate electrode GE may include a conductive material. The gate electrode GE and the first to third semiconductor patterns SP1, SP2, and SP3 may constitute a three-dimensional field effect transistor (e.g., MBCFET or GAAFET). In some embodiment, the channel structure CH may have a single body structure (e.g., a fin structure), not a structure including separated semiconductor patterns.

A pair of gate spacers GS may be respectively disposed at both (e.g., opposite) sides of the gate electrode GE. The gate spacers GS may be extended along the gate electrode GE and in the first direction D1. Upper (e.g., uppermost) surfaces of the gate spacers GS may be higher than an upper (e.g., an uppermost) surface of the gate electrode GE. In some embodiments, the upper (e.g., the uppermost) surfaces of the gate spacers GS may be coplanar with an upper (e.g., an uppermost) surface of a first insulating layer 110, which will be described below. The vertical level may be a relative location (e.g., a distance) from an upper (or a lower) surface of the substrate 100 in a vertical direction (e.g., in the third direction D3). For example, when element A is higher than element B, element A may be located farther than element B from the upper surface of the substrate 100 in the third direction D3.

A gate capping pattern GP may be provided on the gate electrode GE. The gate capping pattern GP may be extended along the gate electrode GE in the first direction D1. The gate capping pattern GP may include an insulating material having an etch selectivity with respect to first and second insulating layers 110 and 120, which will be described below. For example, the gate capping pattern GP may be formed of or include at least one of nitride materials.

A gate insulating layer GI may be provided. The gate insulating layer GI may separate (e.g., electrically separate) the gate electrode GE from the semiconductor patterns SP1, SP2, and SP3. For example, the gate insulating layer GI may be between the gate electrode GE (e.g., the first, second, third, and fourth electrode portions PO1, PO2, PO3, and PO4). The gate insulating layer GI may be in contact with the gate electrode GE (e.g., the first, second, third, and fourth electrode portions PO1, PO2, PO3, and PO4) and the semiconductor patterns SP1, SP2, and SP3. The gate insulating layer GI may include an insulating material. As an example, the gate insulating layer GI may be formed of or include at least one of oxide materials.

The first insulating layer 110 may be provided on the gate spacers GS and the source/drain patterns SD. An upper (e.g., an uppermost) surface of the first insulating layer 110 may be coplanar with an upper (e.g., an uppermost) surface of the gate capping pattern GP and an upper (e.g., an uppermost) surface of the gate spacer GS. A second insulating layer 120 may be provided on the first insulating layer 110 and the gate capping pattern GP. A cover insulating layer 130 may be provided on the second insulating layer 120. The first insulating layer 110, the second insulating layer 120, and the cover insulating layer 130 may include an insulating material. As an example, the first insulating layer 110, the second insulating layer 120, and the cover insulating layer 130 may be formed of or include at least one of oxide materials. In some embodiments, each of the first insulating layer 110, the second insulating layer 120, and the cover insulating layer 130 may have a multi-layered structure including a plurality of insulating layers.

Active contacts AC may be provided to extend in (e.g., extend through or penetrate) the first and second insulating layers 110 and 120. The active contact AC may be electrically connected to the source/drain pattern SD. The gate electrode GE may be provided between the active contacts AC, which are adjacent to each other in the second direction D2. The active contact AC may be a bar-shaped pattern extending in the first direction D1.

In some embodiments, a metal-semiconductor compound layer may be interposed between the active contact AC and the source/drain pattern SD. In this case, the active contact AC may be electrically connected to the source/drain pattern SD through the metal-semiconductor compound layer. For example, the metal-semiconductor compound layer may be formed of or include titanium-silicide, tantalum-silicide, tungsten-silicide, nickel-silicide, and/or cobalt-silicide.

In some embodiments, the active contact AC may include a conductive pattern and a barrier pattern. The barrier pattern may be on (e.g., cover or overlap) side and lower (e.g., lowermost) surfaces of the conductive pattern. For example, the conductive pattern may be formed of or include aluminum, copper, tungsten, molybdenum, and/or cobalt, and the barrier pattern may be formed of or include titanium, tantalum, tungsten, nickel, cobalt, titanium nitride (TiN), tantalum nitride (TaN), tungsten nitride (WN), nickel nitride (NiN), cobalt nitride (CON), and/or platinum nitride (PtN).

Conductive contacts 131 may be provided to extend in (e.g., extend through or penetrate) the cover insulating layer 130. The conductive contact 131 may electrically connect a first conductive line 143, which will be described below, to the active contact AC or may electrically connect the first conductive line 143 to the gate electrode GE. The conductive contact 131 may include a conductive material.

A first etch stop layer 141 may be provided on the cover insulating layer 130. A first interlayer insulating layer 142 may be provided on the first etch stop layer 141. A second etch stop layer 151 may be provided on the first interlayer insulating layer 142. A second interlayer insulating layer 152 may be provided on the second etch stop layer 151. A third interlayer insulating layer 153 may be provided on the second interlayer insulating layer 152.

The first etch stop layer 141 and the first interlayer insulating layer 142 may include insulating materials having an etch selectivity with respect to each other. As an example, the first etch stop layer 141 may be formed of or include silicon nitride (SiN), silicon carbonitride (SiCN), silicon carbide oxide (SiCO), aluminum nitride (AlN), and/or aluminum oxide (AlO), and the first interlayer insulating layer 142 may be formed of or include low-k dielectric materials, tetraethyl orthosilicate (TEOS), silicon carbide hydroxide (SiCHO), and/or silicon oxide (SiO).

The second etch stop layer 151 and the second interlayer insulating layer 152 may include insulating materials having an etch selectivity with respect to each other. As an example, the second etch stop layer 151 may be formed of or include silicon nitride (SiN), silicon carbonitride (SiCN), silicon carbide oxide (SiCO), aluminum nitride (AlN), and/or aluminum oxide (AlO), and the second interlayer insulating layer 152 may be formed of or include low-k dielectric materials, TEOS, silicon carbide hydroxide (SiCHO), and/or silicon oxide (SiO). The third interlayer insulating layer 153 may include an insulating material.

First conductive lines 143 may be provided to extend in (e.g., extend through or penetrate) the first interlayer insulating layer 142 and the first etch stop layer 141. The first conductive lines 143 may be extended in the second direction D2. The first conductive lines 143 may be spaced apart from each other in the first direction D1. The first conductive lines 143 may include a conductive material. As an example, the first conductive lines 143 may be formed of or include Ru, Mo, W, Cu, and/or Co.

A conductive structure 170 may be provided to extend in (e.g., extend through or penetrate) the second etch stop layer 151, the second interlayer insulating layer 152, and the third interlayer insulating layer 153. The conductive structure 170 may include a lower portion 171 and an upper portion 172 on the lower portion 171. The lower portion 171 of the conductive structure 170 may extend in (e.g., extend through or penetrate) the second etch stop layer 151 and the second interlayer insulating layer 152. The upper portion 172 of the conductive structure 170 may extend in (e.g., extend through or penetrate) the third interlayer insulating layer 153. For example, the lower portion 171 of the conductive structure 170 may be defined as a portion of the conductive structure 170 in the second etch stop layer 151 and the second interlayer insulating layer 152. For example, the upper portion 172 of the conductive structure 170 may be defined as a portion of the conductive structure 170 in the third interlayer insulating layer 153. The lower portion 171 of the conductive structure 170 may be at least partially surrounded (e.g., at least partially enclosed) by the second etch stop layer 151 and the second interlayer insulating layer 152. For example, side surfaces of the lower portion 171 of the conductive structure 170 may be surrounded by the second etch stop layer 151 and the second interlayer insulating layer 152. The upper portion 172 of the conductive structure 170 may be at least partially surrounded (e.g., at least partially enclosed) by the third interlayer insulating layer 153. For example, side surfaces of the upper portion 172 of the conductive structure 170 may be surrounded by the third interlayer insulating layer 153. A boundary between the lower and upper portions 171 and 172 of the conductive structure 170 may be located at substantially the same level (in the third direction D3) as an upper (e.g., an uppermost) surface 152_T of the second interlayer insulating layer 152 and a lower (e.g., a lowermost) surface 153_B of the third interlayer insulating layer 153. The lower portion 171 of the conductive structure 170 may be disposed at a level lower than the upper surface 152_T of the second interlayer insulating layer 152 and the lower surface 153_B of the third interlayer insulating layer 153. The upper portion 172 of the conductive structure 170 may be disposed at a level higher than the upper surface 152_T of the second interlayer insulating layer 152 and the lower surface 153_B of the third interlayer insulating layer 153.

A width of the lower portion 171 of the conductive structure 170 (in the first direction D1 and/or the second direction D2) may decrease as a distance to the first conductive lines 143 decreases (in the third direction D3). As an example, a width W1 of the lower portion 171 of the conductive structure 170 in the second direction D2 may decrease as a distance to the first conductive lines 143 decreases (in the third direction D3), and a width W3 of the lower portion 171 of the conductive structure 170 in the first direction D1 may decrease as a distance to the first conductive lines 143 decreases (in the third direction D3). The width of the lower portion 171 of the conductive structure 170 may decrease as a vertical level (of the lower portion 171 of the conductive structure 170) is lowered.

A width of the upper portion 172 of the conductive structure 170 (in the first direction D1 and/or the second direction D2) may increase as a distance to the first conductive lines 143 decreases (in the third direction D3). As an example, a width W2 of the upper portion 172 of the conductive structure 170 in the second direction D2 may increase as a distance to the first conductive lines 143 decreases (in the third direction D3), and a width W4 of the upper portion 172 of the conductive structure 170 in the first direction D1 may increase as a distance to the first conductive lines 143 decreases (in the third direction D3). The width of the upper portion 172 of the conductive structure 170 may increase as a vertical level (of the upper portion 172 of the conductive structure 170) is lowered.

An intervening portion IN of the first interlayer insulating layer 142 may be defined between a pair of the first conductive lines 143, which are adjacent to each other in the first direction D1. The intervening portion IN of the first interlayer insulating layer 142 may be in contact with the pair of the first conductive lines 143, which are adjacent to each other in the first direction D1.

A lower (e.g., a lowermost) surface 170_B of the conductive structure 170 may be in contact with upper (e.g., uppermost) surfaces 143_T of the pair of the first conductive lines 143, which are adjacent to each other in the first direction D1, and an upper (e.g., an uppermost) surface IN_T of the intervening portion IN. The upper surfaces 143_T of the pair of the first conductive lines 143, which are adjacent to each other in the first direction D1, may be coplanar with the upper surface IN_T of the intervening portion IN. The upper surfaces 143_T of the pair of the first conductive lines 143, which are adjacent to each other in the first direction D1, may be placed at the same level as the upper surface IN_T of the intervening portion IN (in the third direction D3). The lower surface 170_B of the conductive structure 170 may be flat. The lower surface 170_B of the conductive structure 170 may be a lower (e.g., a lowermost) surface of the lower portion 171 of the conductive structure 170.

A width of the lower surface 170_B of the conductive structure 170 in the first direction D1 may be larger than a sum of widths of the upper surfaces 143_T of the pair (e.g., two) of the first conductive lines 143, which are adjacent to each other in the first direction D1, and a width of the upper surface IN_T of the intervening portion IN (between the pair of the first conductive lines 143) in the first direction D1.

The conductive structure 170 may include a barrier layer 174 and a conductive layer 173 on the barrier layer 174. The barrier layer 174 may be in contact with the upper (e.g., the uppermost) surfaces 143_T of the first conductive lines 143, which are adjacent to each other in the first direction D1, and the upper (e.g., the uppermost) surface IN_T of the intervening portion IN. The barrier layer 174 may include a conductive material. As an example, the barrier layer 174 may be formed of or include titanium (Ti), titanium nitride (TiN), tantalum (Ta), tantalum nitride (TaN), and/or transition metal chalcogenides (e.g., MoS and WS). The conductive layer 173 may include a conductive material. As an example, the conductive layer 173 may be formed of or include Ru, Mo, W, Cu, and/or Co.

A second conductive line 160 may be provided to extend in (e.g., extend through or penetrate) the third interlayer insulating layer 153. The second conductive line 160 may be at least partially surrounded (e.g., at least partially enclosed) by the third interlayer insulating layer 153. For example, the third interlayer insulating layer 153 may extend around side surfaces of the second conductive line 160. A lower (e.g., a lowermost) surface 160_B of the second conductive line 160 may be in contact with the upper (e.g., the uppermost) surface 152_T of the second interlayer insulating layer 152. The second conductive line 160 may be disposed at the same level as the upper portion 172 of the conductive structure 170. For example, the second conductive line 160 may overlap the upper portion 172 of the conductive structure 170 in the first direction D1 and/or the second direction D2. The lower (e.g., the lowermost) surface 160_B of the second conductive line 160 may be located at substantially the same level as the boundary between the lower and upper portions 171 and 172 of the conductive structure 170 (in the third direction D3).

A width of the second conductive line 160 (in the first direction D1 and/or the second direction D2) may increase as a distance to the first conductive lines 143 decreases (in the third direction D3). As an example, a width W5 of the second conductive line 160 in the first direction D1 may increase as a distance to the first conductive lines 143 decreases (in the third direction D3). The width of the second conductive line 160 may increase as a vertical level (of the second conductive line 160) is lowered.

The second conductive line 160 may include a line barrier layer 161 and a line conductive layer 162 on the line barrier layer 161. A lower (e.g., a lowermost) surface of the line barrier layer 161 may be the lower (e.g., the lowermost) surface 160_B of the second conductive line 160. A side surface 161_S of the line barrier layer 161 and a side surface 162_S of the line conductive layer 162 may be in contact with a side surface of the third interlayer insulating layer 153. The side surface 161_S of the line barrier layer 161 may be coplanar with the side surface 162_S of the line conductive layer 162. The side surface 161_S of the line barrier layer 161 and the side surface 162_S of the line conductive layer 162 may be inclined at an angle to the upper (e.g., the uppermost) surface 152_T of the second interlayer insulating layer 152 and the lower (e.g., the lowermost) surface 153_B of the third interlayer insulating layer 153. An angle between the side surface 161_S of the line barrier layer 161 and the lower (e.g., the lowermost) surface 153_B of the third interlayer insulating layer 153 may be an obtuse angle at a portion where the side surface 161_S of the line barrier layer 161 is connected to the lower (e.g., the lowermost) surface 153_B of the third interlayer insulating layer 153.

The line barrier layer 161 may include the same conductive material as the barrier layer 174. The line conductive layer 162 may include the same conductive material as the conductive layer 173.

Referring to FIGS. 4D and 4E, the barrier layer 174 may include a lower portion 174a and an upper portion 174b on the lower portion 174a. The conductive layer 173 may include a lower portion 173a and an upper portion 173b on the lower portion 173a. The lower portion 171 of the conductive structure 170 may include the lower portion 174a of the barrier layer 174 and the lower portion 173a of the conductive layer 173. The upper portion 172 of the conductive structure 170 may include the upper portion 174b of the barrier layer 174 and the upper portion 173b of the conductive layer 173. The lower portion 173a of the conductive layer 173 may be at least partially (e.g., at least partially enclosed) by the lower portion 174a of the barrier layer 174. For example, the lower portion 174a of the barrier layer 174 may extend around side surfaces of the lower portion 173a of the conductive layer 173.

An outer side surface 174a_S1 of the lower portion 174a of the barrier layer 174 may be in contact with a side surface of the second interlayer insulating layer 152. For example, the lower portion 174a of the barrier layer 174 may be defined as a portion of the barrier layer 174 in the second interlayer insulating layer 152. An inner side surface 174a_S2 of the lower portion 174a of the barrier layer 174 may be in contact with the lower portion 173a of the conductive layer 173. The outer and inner side surfaces 174a_S1 and 174a_S2 of the lower portion 174a of the barrier layer 174 may be inclined at an angle to the upper (e.g., the uppermost) surface 152_T of the second interlayer insulating layer 152 and the lower (e.g., the lowermost) surface 153_B of the third interlayer insulating layer 153. When viewed in the sectional views of FIG. 4D or 4E, the outer and inner side surfaces 174a_S1 and 174a_S2 of the lower portion 174a of the barrier layer 174 may be extended to be parallel to each other. The lower portion 174a of the barrier layer 174 may have a substantially constant width (in horizontal directions, such as the second direction D2). As an example, a width W7 of the lower portion 174a of the barrier layer 174 in the second direction D2 may be substantially constant (regardless of the level of the lower portion 174a of the barrier layer 174 in the third direction D3). The outer side surface 174a_S1 of the lower portion 174a of the barrier layer 174 may be an outer side surface of the lower portion 171 of the conductive structure 170.

An outer side surface 174b_S1 of the upper portion 174b of the barrier layer 174 may be in contact with the side surface of the third interlayer insulating layer 153. For example, the upper portion 174b of the barrier layer 174 may be defined as a portion of the barrier layer 174 in the third interlayer insulating layer 153. An inner side surface 174b_S2 of the upper portion 174b of the barrier layer 174 may be in contact with the upper portion 173b of the conductive layer 173. The outer and inner side surfaces 174b_S1 and 174b_S2 of the upper portion 174b of the barrier layer 174 may be inclined at an angle to the upper (e.g., the uppermost) surface 152_T of the second interlayer insulating layer 152 and the lower (e.g., the lowermost) surface 153_B of the third interlayer insulating layer 153. For example, the inner side surface 174b_S2 of the upper portion 174b of the barrier layer 174 may be inclined at an angle to an imaginary line extending from the upper (e.g., the uppermost) surface 152_T of the second interlayer insulating layer 152 and/or the lower (e.g., the lowermost) surface 153_B of the third interlayer insulating layer 153 in the second direction D2. When viewed in the sectional views of FIG. 4D or 4E, the outer and inner side surfaces 174b_S1 and 174b_S2 of the upper portion 174b of the barrier layer 174 may be extended in two different directions that are not parallel to each other. A width of the upper portion 174b of the barrier layer 174 (in the first direction D1 and/or the second direction D2) may increase as a distance to the first conductive lines 143 decreases (in the third direction D3). As an example, a width W6 of the upper portion 174b of the barrier layer 174 in the second direction D2 may increase as a distance to the first conductive lines 143 decreases. The width of the upper portion 174b of the barrier layer 174 may increase as a vertical level (of the upper portion 174b of the barrier layer 174) is lowered.

The inner side surface 174a_S2 of the lower portion 174a of the barrier layer 174 may be coplanar with the inner side surface 174b_S2 of the upper portion 174b of the barrier layer 174. When viewed in the sectional views of FIGS. 4D and 4E, the inner side surface 174a_S2 of the lower portion 174a of the barrier layer 174 and the inner side surface 174b_S2 of the upper portion 174b of the barrier layer 174 may be located on (may be formed of) a single straight line.

The outer side surface 174b_S1 of the upper portion 174b of the barrier layer 174 may include a first portion P1. The outer side surface 174a_S1 of the lower portion 174a of the barrier layer 174 may include a second portion P2. The first portion P1 and the second portion P2 may be spaced apart from each other. The upper portion 174b of the barrier layer 174 may include a connection surface 174b_S3 connecting the first portion P1 to the second portion P2. For example, the connection surface 174b_S3 may be between the first portion P1 and the second portion P2 (in the second direction D2). The connection surface 174b_S3 may be in contact with the upper (e.g., the uppermost) surface 152_T of the second interlayer insulating layer 152. For example, the connection surface 174b_S3 may be coplanar with the upper surface 152_T of the second interlayer insulating layer 152 and the lower surface 153_B of the third interlayer insulating layer 153.

The outer side surface 174b_S1 of the upper portion 174b of the barrier layer 174 may include a third portion P3. The outer side surface 174a_S1 of the lower portion 174a of the barrier layer 174 may include a fourth portion P4. The third portion P3 and the fourth portion P4 may be connected to each other. The connecting portion between the third portion P3 and the fourth portion P4 may be at (substantially) the same vertical level of the upper surface 152_T of the second interlayer insulating layer 152 and/or the lower surface 153_B of the third interlayer insulating layer 153.

An upper (e.g., an uppermost) surface 174b_S4 of the upper portion 174b of the barrier layer 174 may connect the inner side surface 174b_S2 of the upper portion 174b of the barrier layer 174 to the outer side surface 174b_S1 of the upper portion 174b of the barrier layer 174. The upper (e.g., the uppermost) surface 174b_S4 of the upper portion 174b of the barrier layer 174 may be between the inner side surface 174b_S2 of the upper portion 174b of the barrier layer 174 and the outer side surface 174b_S1 of the upper portion 174b of the barrier layer 174 in the second direction D2. The upper (e.g., the uppermost) surface 174b_S4 of the upper portion 174b of the barrier layer 174 may be in contact with the upper portion 173b of the conductive layer 173.

The lower portion 173a of the conductive layer 173 may be spaced apart from the second interlayer insulating layer 152 by the lower portion 174a of the barrier layer 174. The upper portion 173b of the conductive layer 173 may be in contact with the third interlayer insulating layer 153. An outer side surface 173b_S1 of the upper portion 173b of the conductive layer 173 may be in contact with the side surface of the third interlayer insulating layer 153.

The outer side surface 173b_S1 of the upper portion 173b of the conductive layer 173 may be coplanar with the outer side surface 174b_S1 of the upper portion 174b of the barrier layer 174. When viewed in the sectional views of FIGS. 4D and 4E, the outer side surface 173b_S1 of the upper portion 173b of the conductive layer 173 and the outer side surface 174b_S1 of the upper portion 174b of the barrier layer 174 may be located on (may be formed of) a single straight line. An outer side surface of the upper portion 172 of the conductive structure 170 may include the outer side surface 174b_S1 of the upper portion 174b of the barrier layer 174 and the outer side surface 173b_S1 of the upper portion 173b of the conductive layer 173.

An angle AN1 between the first portion P1 and the lower (e.g., the lowermost) surface 153_B of the third interlayer insulating layer 153 may be an obtuse angle at a portion where the first portion P1 is connected to the lower (e.g., the lowermost) surface 153_B of the third interlayer insulating layer 153. An angle AN2 between the second portion P2 and the upper (e.g., the uppermost) surface 152_T of the second interlayer insulating layer 152 may be an obtuse angle at a portion where the second portion P2 is connected to the upper (e.g., the uppermost) surface 152_T of the second interlayer insulating layer 152. An angle AN3 between the third portion P3 and the lower (e.g., the lowermost) surface 153_B of the third interlayer insulating layer 153 may be an obtuse angle at a portion where the third portion P3 is connected to the lower (e.g., the lowermost) surface 153_B of the third interlayer insulating layer 153. An angle AN4 between the fourth portion P4 and the upper (e.g., the uppermost) surface 152_T of the second interlayer insulating layer 152 may be an obtuse angle at a portion where the fourth portion P4 is connected to the upper (e.g., the uppermost) surface 152_T of the second interlayer insulating layer 152.

In the semiconductor device according to some embodiments of the inventive concept, the lower (e.g., the lowermost) surface 170_B of the conductive structure 170 may have a substantially flat shape, and thus, the first conductive lines 143 and the intervening portion IN, which are placed below the conductive structure 170, may not be damaged in the process of forming the conductive structure 170.

In the semiconductor device according to some embodiments of the inventive concept, since the lower (e.g., the lowermost) surface 170_B of the conductive structure 170 has a substantially flat shape, the barrier layer 174 may have a constant (a uniform) thickness and the reliability of the barrier layer 174 may be improved.

In the semiconductor device according to some embodiments of the inventive concept, since a pair of the first conductive lines 143 are connected (e.g., electrically connected) to each other through the conductive structure 170, it may be possible to omit additional interconnection structures for electrically connecting the pair of the first conductive lines 143 to each other. As a result, it may be possible to reduce a size of the semiconductor device and increase a degree of freedom in designing the semiconductor device.

In the semiconductor device according to some embodiments of the inventive concept, the largest width of the upper portion 172 of the conductive structure 170 in the first direction D1 may be equal to the largest width of the lower portion 171 of the conductive structure 170 in the first direction D1. Thus, it may be possible to reduce a length of the upper portion 172 of the conductive structure 170 in the first direction D1 and increase a degree of freedom in designing a semiconductor device.

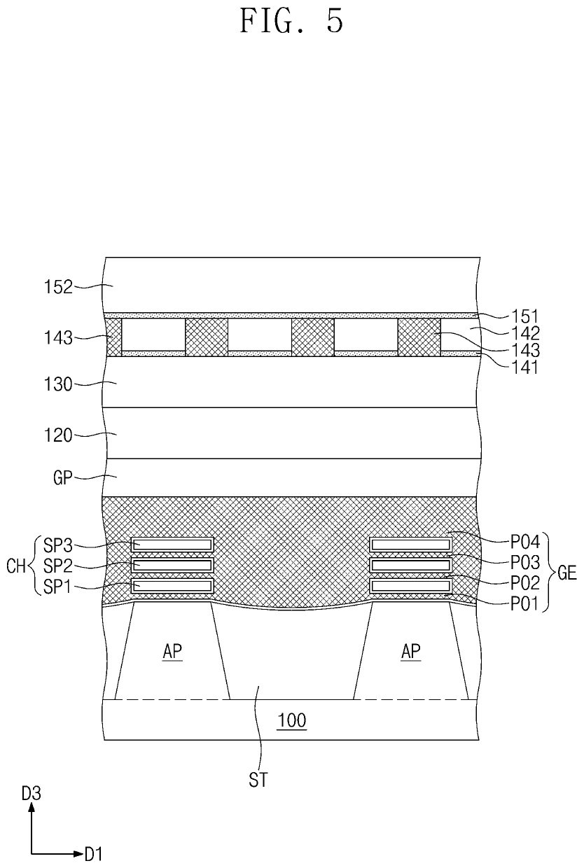

FIGS. 5, 6, 7, 8, 9, and 10 are sectional views illustrating a method of fabricating the semiconductor device of FIGS. 4A to 4E.

Referring to FIG. 5, the active patterns AP may be formed in the substrate 100. The device isolation layer ST may be formed. The channel structures CH, the source/drain patterns SD (e.g., see FIG. 4B), the gate electrodes GE, the gate insulating layers GI (e.g., see FIG. 4B), the gate spacers GS (e.g., see FIG. 4B), the gate capping patterns GP, the first insulating layer 110 (e.g., see FIG. 4B), the second insulating layer 120, and the active contacts AC may be formed.

The cover insulating layer 130 may be formed on the second insulating layer 120. The conductive contact 131 (e.g., see FIG. 4B) may be formed to extend in (e.g., penetrate) the cover insulating layer 130.

The first etch stop layer 141 may be formed on the cover insulating layer 130. The first interlayer insulating layer 142 may be formed on the first etch stop layer 141. The first conductive lines 143 may be formed in the first etch stop layer 141 and the first interlayer insulating layer 142. The formation of the first conductive lines 143 may include etching the first interlayer insulating layer 142 and the first etch stop layer 141 and forming the first conductive lines 143 in empty spaces, which are formed by etching the first interlayer insulating layer 142 and the first etch stop layer 141. The first etch stop layer 141 may be used as an etch stop layer in the process of etching the first interlayer insulating layer 142.

The second etch stop layer 151 may be formed on the first interlayer insulating layer 142 and the first conductive lines 143. The second interlayer insulating layer 152 may be formed on the second etch stop layer 151.

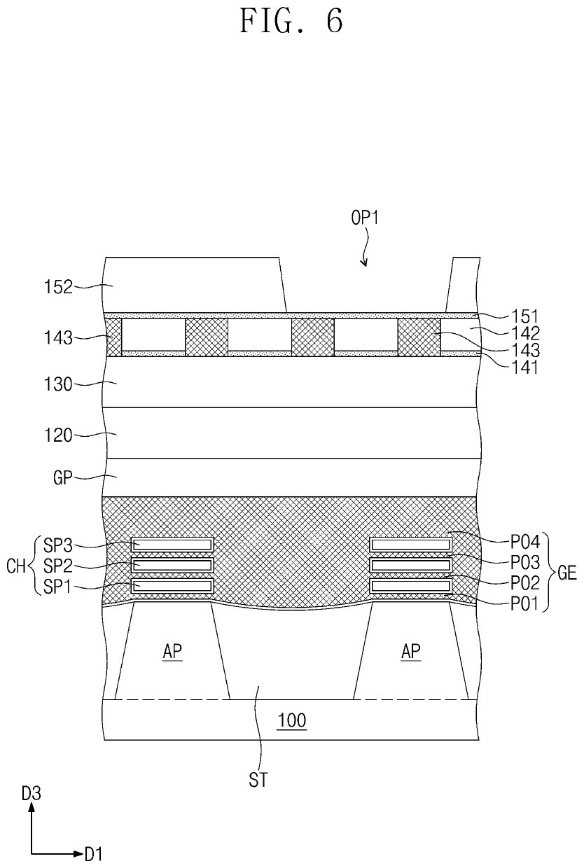

Referring to FIG. 6, a first opening OP1 may be formed to extend in (e.g., extend through or penetrate) the second interlayer insulating layer 152. The first opening OP1 may be formed by etching the second interlayer insulating layer 152. The first opening OP1 may be at least partially surrounded (e.g., at least partially enclosed) by the second interlayer insulating layer 152. The first opening OP1 may be formed to expose at least a portion of an upper (e.g., an uppermost) surface of the second etch stop layer 151. The second etch stop layer 151 may be used as an etch stop layer in a process of forming the first opening OP1. A width of the first opening OP1 in the first direction D1 may decrease as a distance to the first conductive lines 143 decreases (in the third direction D3). The (exposed portion of the) upper (e.g., the uppermost) surface of the second etch stop layer 151 and (exposed) the side surface of the second interlayer insulating layer 152 may define the first opening OP1.

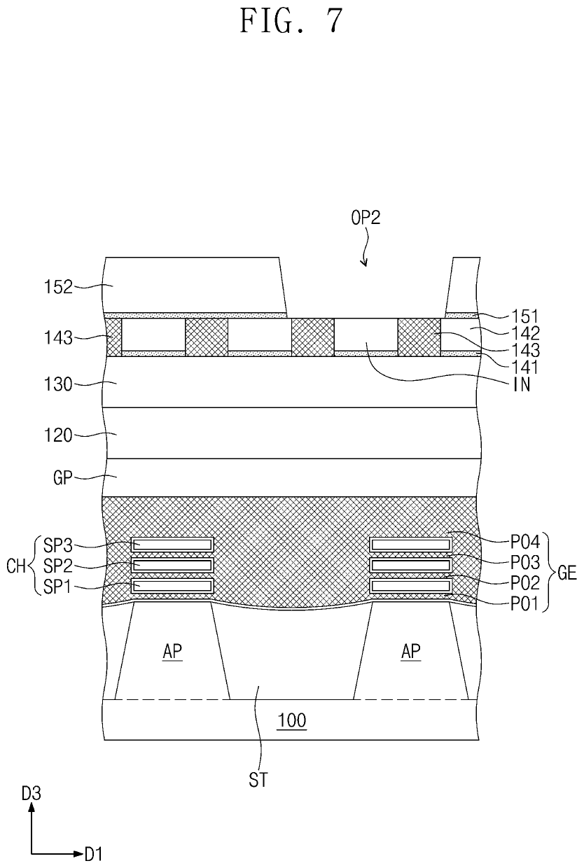

Referring to FIG. 7, the first opening OP1 may be expanded. For example, the first opening OP1 may be expanded by etching (the exposed portion of the upper surface of) the second etch stop layer 151 exposed by the first opening OP1. The (portions of the) first conductive lines 143 and the intervening portion IN of the first interlayer insulating layer 142 may be exposed through the expanded first opening OP1. The expanded first opening OP1 may be referred to as a second opening OP2. An upper (e.g., an uppermost) surface of the first interlayer insulating layer 142, upper (e.g., uppermost) surfaces of the first conductive lines 143, a side surface of the second etch stop layer 151, and the side surface of the second interlayer insulating layer 152 may define the second opening OP2. For example, the second opening OP2 may expose (at least a portion of) the upper (e.g., the uppermost) surface of the first interlayer insulating layer 142 (e.g., the intervening portion IN), the upper (e.g., the uppermost) surfaces of the first conductive lines 143, the side surface of the second etch stop layer 151, and the side surface of the second interlayer insulating layer 152

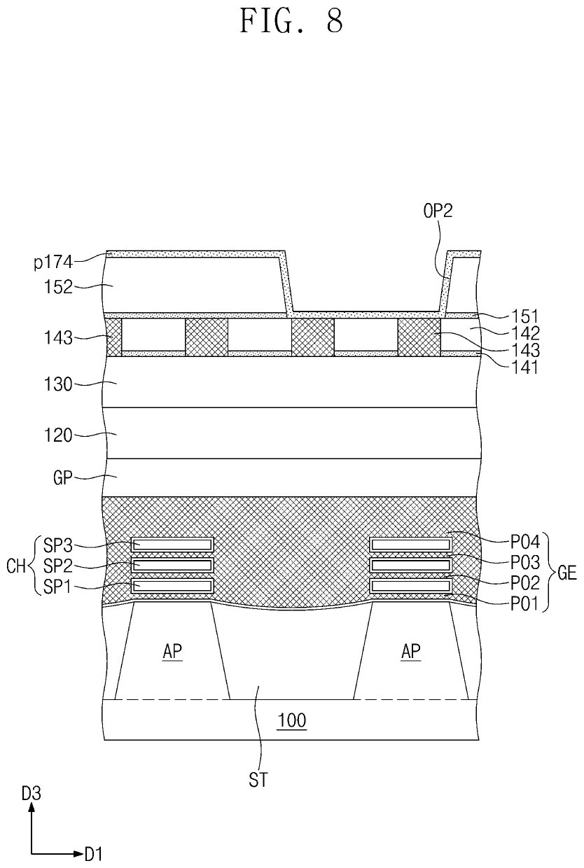

Referring to FIG. 8, a preliminary barrier layer p174 may be formed. The preliminary barrier layer p174 may be conformally formed on an upper (e.g., an uppermost) surface of the second interlayer insulating layer 152, the side surface of the second interlayer insulating layer 152, the upper (e.g., the uppermost) surfaces of the first conductive lines 143, the upper (e.g., the uppermost) surface of the first interlayer insulating layer 142, and the side surface of the second etch stop layer 151. The preliminary barrier layer p174 may be in contact with the upper (e.g., the uppermost) surface of the second interlayer insulating layer 152, the side surface of the second interlayer insulating layer 152, the upper (e.g., the uppermost) surfaces of the first conductive lines 143, the upper (e.g., the uppermost) surface of the first interlayer insulating layer 142, and the side surface of the second etch stop layer 151.

The preliminary barrier layer p174 may include a conductive material. In some embodiments, the preliminary barrier layer p174 may be formed of or include titanium (Ti), titanium nitride (TiN), tantalum (Ta), tantalum nitride (TaN), and/or transition metal chalcogenides (e.g., MoS and WS).

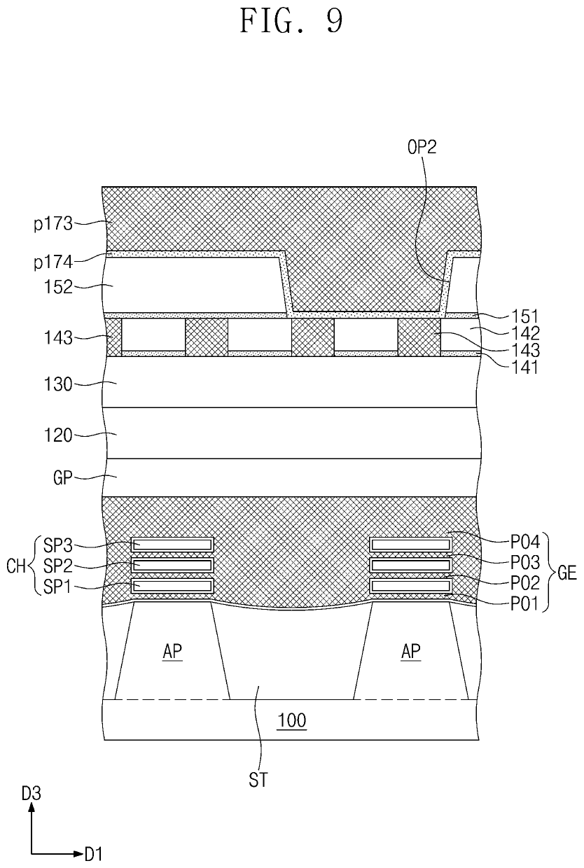

Referring to FIG. 9, a preliminary conductive layer p173 may be formed on the preliminary barrier layer p174. The preliminary conductive layer p173 may include a conductive material. In some embodiment, the preliminary conductive layer p173 may be formed of or include Ru, Mo, W, Cu, and/or Co.

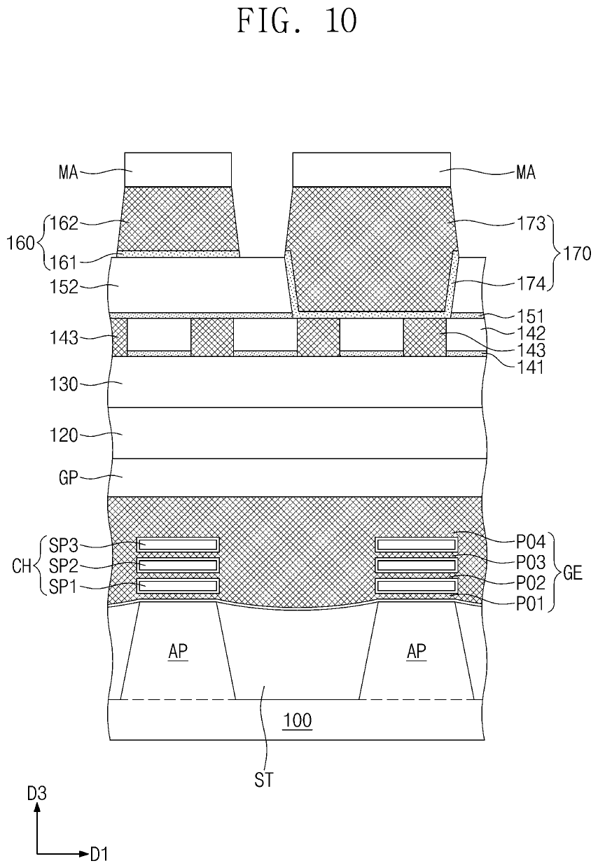

Referring to FIG. 10, a mask layer MA may be formed on the preliminary conductive layer p173. The formation of the mask layer MA may include forming a preliminary mask layer on the preliminary conductive layer p173 and patterning the preliminary mask layer to form the mask layer MA. The mask layer MA may include an insulating material.

The preliminary conductive layer p173 and the preliminary barrier layer p174 may be etched using the mask layer MA as an etch mask. The barrier layer 174 and the line barrier layer 161, which are spaced apart from each other, may be formed as a result of the etching of the preliminary barrier layer p174. The conductive layer 173 and the line conductive layer 162 may be formed as a result of the etching of the preliminary conductive layer p173. The line barrier layer 161 and the line conductive layer 162 may constitute the second conductive line 160. The barrier layer 174 and the conductive layer 173 may constitute the conductive structure 170. The lower portion 171 (e.g., see FIGS. 4B and 4C) of the conductive structure 170 may be disposed in the second opening OP2. The upper portion 172 (e.g., see FIGS. 4B and 4C) of the conductive structure 170 may be disposed at a level higher than the second opening OP2 in the third direction D3.

In some embodiments, the preliminary conductive layer p173 and the preliminary barrier layer p174 may be etched such that a width of the upper portion 172 of the conductive structure 170 (in the first direction D1 and/or the second direction D2) is equal to or larger than a width of the lower portion 171 of the conductive structure 170 (in the first direction D1 and/or the second direction D2).

In some embodiments, when measured in the first direction D1, the largest width (in the first direction D1 and/or the second direction D2) of a portion of the mask layer MA overlapped with the second opening OP2 in the third direction D3 may be smaller than the largest width (in the first direction D1 and/or the second direction D2) of the second opening OP2.

At least a portion of the upper (e.g., the uppermost) surface of the second interlayer insulating layer 152 may be exposed, as a result of the etching of the preliminary conductive layer p173 and the preliminary barrier layer p174.

Referring to FIGS. 4B and 4C, the mask layer MA may be removed. The third interlayer insulating layer 153 may be formed.

In the fabrication method according to some embodiment of the inventive concept, since the first opening OP1 is formed to have a width (in the first direction D1 and/or the second direction D2) larger than (or equal to) (the width of) the first conductive line 143 and (the width of) the lower portion 171 of the conductive structure 170 (in the first direction D1 and/or the second direction D2) is formed in the first opening OP1, it may be possible to reduce a technical difficulty in the process of forming the conductive structure 170.

In the fabrication method according to some embodiments of the inventive concept, since the upper portion 172 of the conductive structure 170 is formed by etching the preliminary conductive layer p173 and the preliminary barrier layer p174, it may be possible to reduce a length of the upper portion 172 of the conductive structure 170.

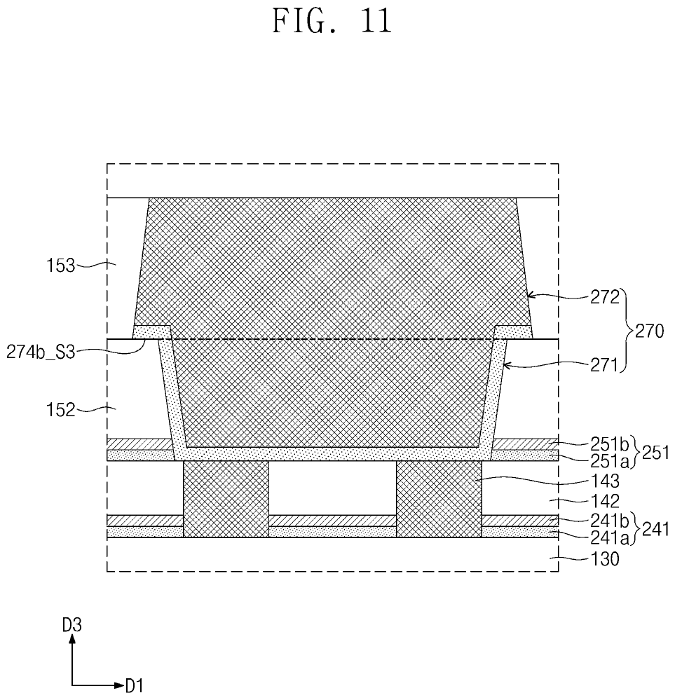

FIG. 11 is an enlarged sectional view illustrating a semiconductor device according to some embodiments of the inventive concept. The semiconductor device of FIG. 11 may be similar to the semiconductor device described with reference to FIGS. 4A to 4E, except for the features to be described below. FIG. 11 may correspond to the portion E3 of FIG. 4C.

Referring to FIG. 11, a first etch stop layer 241 between the cover insulating layer 130 and the first interlayer insulating layer 142 may include a first layer 241a and a second layer 241b. The first layer 241a and the second layer 241b may be formed of or include different insulating materials from each other. In some embodiments, the first etch stop layer 241 may include three or more layers.

A second etch stop layer 251 between the first interlayer insulating layer 142 and the second interlayer insulating layer 152 may include a third layer 251a and a fourth layer 251b. The third layer 251a and the fourth layer 251b may be formed of or include different insulating materials from each other. In some embodiments, the second etch stop layer 251 may include three or more layers.

A connection surface 274b_S3 of an upper portion 272 of a conductive structure 270 may connect an outer side surface of the upper portion 272 of the conductive structure 270 to an outer side surface of a lower portion 271 of the conductive structure 270. For example, the connection surface 274b_S3 of the upper portion 272 of the conductive structure 270 may be between the outer side surface of the upper portion 272 of the conductive structure 270 and the outer side surface of the lower portion 271 of the conductive structure 270 in the first direction D1. The connection surface 274b_S3 of the upper portion 272 of the conductive structure 270 may have a ring shape, when viewed in a plan view.

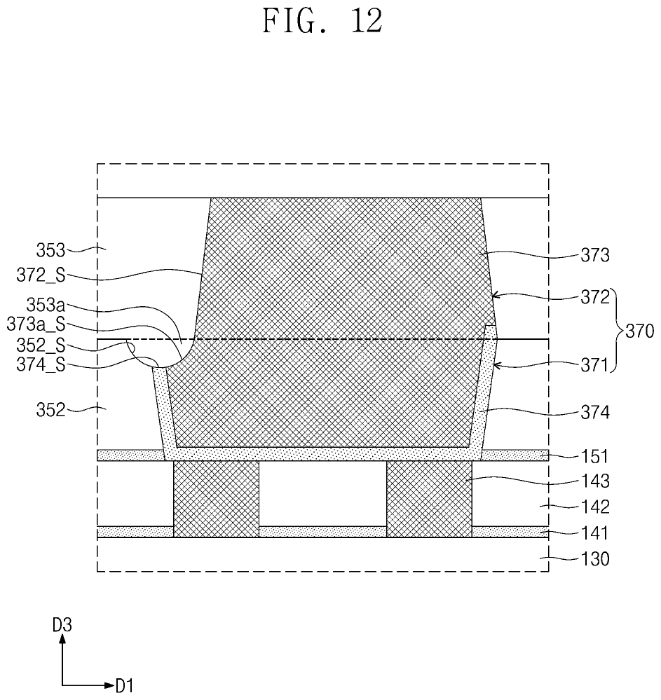

FIG. 12 is an enlarged sectional view illustrating a semiconductor device according to some embodiments of the inventive concept. The semiconductor device of FIG. 12 may be similar to the semiconductor device of FIGS. 4A to 4E, except for the features to be described below. FIG. 12 may correspond to a portion E3 of FIG. 4C.

Referring to FIG. 12, the largest width of an upper portion 372 of a conductive structure 370 in the first direction D1 may be smaller than the largest width of a lower portion 371 of the conductive structure 370 in the first direction D1. A third interlayer insulating layer 353 may include a filling portion 353a, which protrudes toward the lower portion 371 of the conductive structure 370 and a second interlayer insulating layer 352. For example, the third interlayer insulating layer 353 may include the filling portion 353a at least partially extending into the lower portion 371 of the conductive structure 370 and the second interlayer insulating layer 352. The filling portion 353a may be provided at a level lower (in the third direction D3) than the upper portion 372 of the conductive structure 370. The filling portion 353a may be provided between the lower portion 371 of the conductive structure 370 and the second interlayer insulating layer 352.

The second interlayer insulating layer 352 may include a first curved surface 352_S in contact with the filling portion 353a. A barrier layer 374 may include a second curved surface 374_S in contact with the filling portion 353a. A lower portion of a conductive layer 373 may include a third curved surface 373a_S in contact with the filling portion 353a. A bottom surface of the filling portion 353a may have a curved shape. The lower surface of the filling portion 353a may be in contact with the first curved surface 352_S, the second curved surface 374_S, and the third curved surface 373a_S. The third curved surface 373a_S may be connected to an outer side surface 372_S of the upper portion 372 of the conductive structure 370.

As a result of the process of etching the preliminary conductive layer and the preliminary barrier layer, the first curved surface 352_S, the second curved surface 374_S, and the third curved surface 373a_S may be formed. In the process of forming the third interlayer insulating layer 353, an empty space, which is defined by the first curved surface 352_S, the second curved surface 374_S, and the third curved surface 373a_S, may be filled with the filling portion 353a.

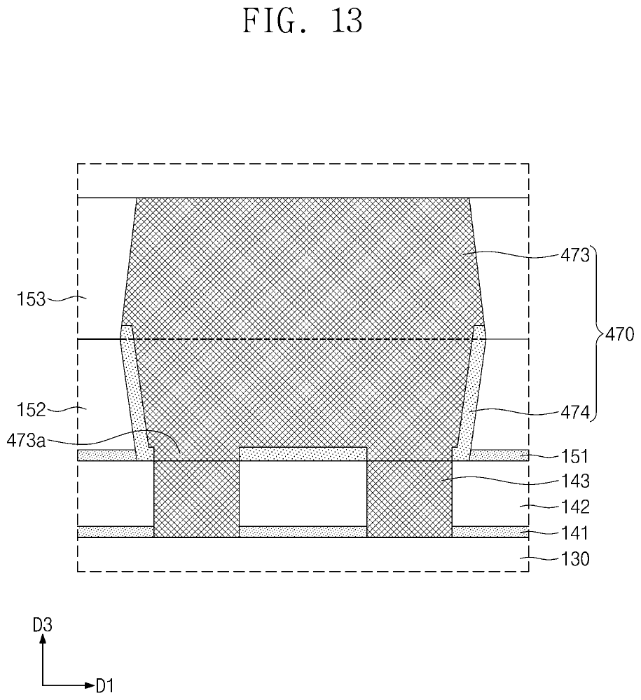

FIG. 13 is an enlarged sectional view illustrating a semiconductor device according to some embodiments of the inventive concept. The semiconductor device of FIG. 13 may be similar to the semiconductor device described with reference to FIGS. 4A to 4E, except for the features to be described below. FIG. 13 may correspond to the portion E3 of FIG. 4C.

Referring to FIG. 13, a conductive layer 473 of a conductive structure 470 may include penetration portions 473a extending in (e.g., extending through or penetrating) a barrier layer 474. The penetration portion 473a may be in contact with the upper (e.g., the uppermost) surface of the first conductive line 143.

The barrier layer 474 may be in contact with the first interlayer insulating layer 142, the second etch stop layer 151, and the second interlayer insulating layer 152. The conductive layer 473 may be spaced apart from the first interlayer insulating layer 142, the second etch stop layer 151, and the second interlayer insulating layer 152 by the barrier layer 474.

Similar to the embodiments of FIG. 8, the preliminary barrier layer may be selectively formed on the first interlayer insulating layer 142, the second etch stop layer 151, and the second interlayer insulating layer 152 in the process of forming the preliminary barrier layer. The preliminary barrier layer may not be formed on the first conductive lines 143. The first conductive lines 143 may be (at least partially) exposed through the preliminary barrier layer.

Similar to the embodiment of FIG. 9, in the process of forming the preliminary conductive layer, the first conductive lines 143, which is exposed through the preliminary barrier layer, may be in contact with the preliminary conductive layer.

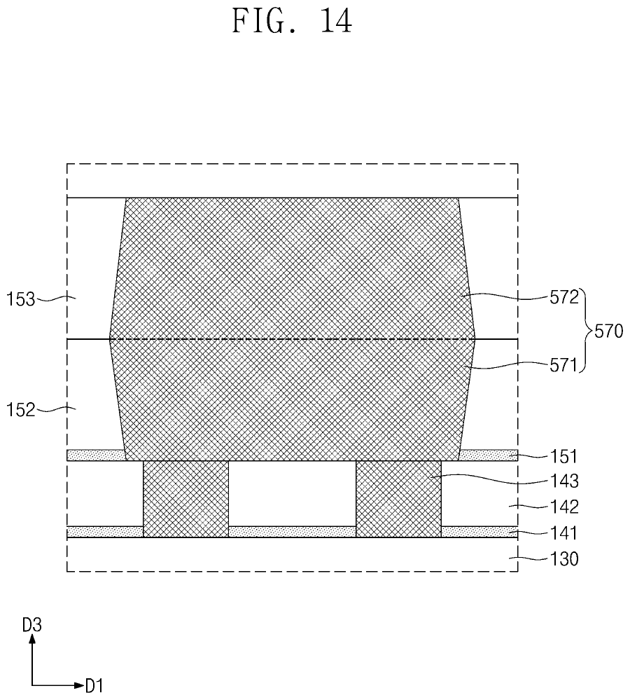

FIG. 14 is an enlarged sectional view illustrating a semiconductor device according to some embodiments of the inventive concept. The semiconductor device of FIG. 14 may be similar to the semiconductor device described with reference to FIGS. 4A to 4E, except for the features to be described below. FIG. 14 may correspond to the portion E3 of FIG. 4C.

Referring to FIG. 14, a conductive structure 570 may not include a barrier layer. The conductive structure 570 may include an upper portion 572 and a lower portion 571, which are connected to each other to form a single object without an interface (a visible interface therebetween). The conductive structure 570 may be formed of or include Ru, Mo, W, Cu, and/or Co.

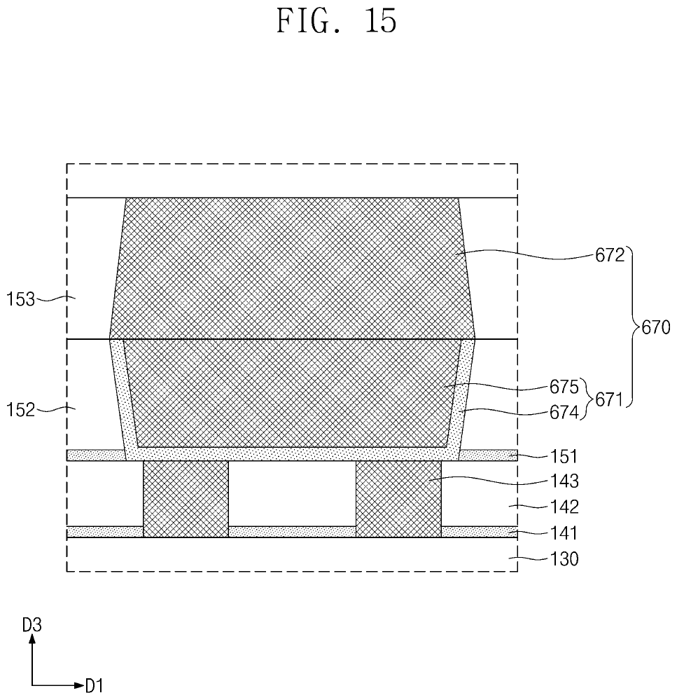

FIG. 15 is an enlarged sectional view illustrating a semiconductor device according to some embodiments of the inventive concept. The semiconductor device of FIG. 15 may be similar to the semiconductor device described with reference to FIGS. 4A to 4E, except for the features to be described below. FIG. 15 may correspond to the portion E3 of FIG. 4C.

Referring to FIG. 15, a lower portion 671 of a conductive structure 670 may include a barrier layer 674 and a first conductive layer 675 in (on) the barrier layer 674. The conductive structure 670 may further include a second conductive layer 672. The second conductive layer 672 may be an upper portion of the conductive structure 670.

The first and second conductive layers 675 and 672 may include different conductive materials from each other. In some embodiments, the first and second conductive layers 675 and 672 may be formed of or include two different materials, respectively, each of which is chosen from the group consisting of Ru, Mo, W, Cu, Co, alloys, or combinations thereof.

An upper (e.g., an uppermost) surface of the barrier layer 674 and an upper (e.g., an uppermost) surface of the first conductive layer 675 may be in contact with a lower (e.g., a lowermost) surface of the second conductive layer 672. The upper (e.g., the uppermost) surface of the barrier layer 674, the upper (e.g., the uppermost) surface of the first conductive layer 675, and the upper (e.g., the uppermost) surface of the second interlayer insulating layer 152 may be coplanar with each other. A lower (e.g., a lowermost) surface of the second conductive layer 672 may be coplanar with a lower (e.g., a lowermost) surface of the third interlayer insulating layer 153. The upper (e.g., the uppermost) surface of the barrier layer 674, the upper (e.g., the uppermost) surface of the first conductive layer 675, the upper (e.g., the uppermost) surface of the second interlayer insulating layer 152, the lower (e.g., the lowermost) surface of the second conductive layer 672, and the lower (e.g., the lowermost) surface of the third interlayer insulating layer 153 may be located at substantially the same level (in the third direction D3).

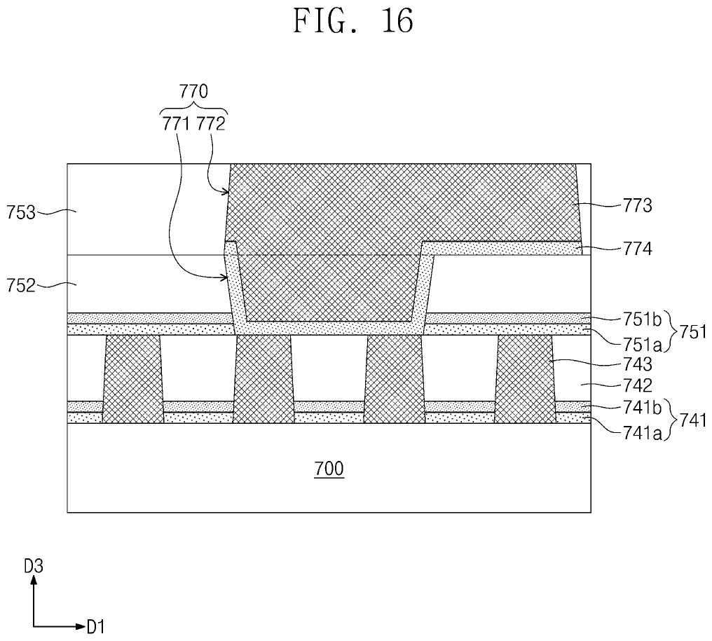

FIG. 16 is a sectional view illustrating a semiconductor device according to some embodiments of the inventive concept.

Referring to FIG. 16, the semiconductor device may include a substrate 700. A first etch stop layer 741 may be provided on the substrate 700. A first interlayer insulating layer 742 may be provided on the first etch stop layer 741.

In some embodiments, an electronic element and an insulating layer on (e.g., covering or overlapping) the electronic element may be provided between the substrate 700 and the first etch stop layer 741. In some embodiments, the electronic element may include a transistor, a capacitor, resistor, and/or a diode. The electronic element may be electrically connected to a conductive line 743, which will be described below.

The first etch stop layer 741 may include a first layer 741a on the substrate 700 and a second layer 741b on the first layer 741a. The first layer 741a and the second layer 741b may be formed of or include different insulating materials from each other. The first interlayer insulating layer 742 may include an insulating material having an etch selectivity with respect to the first etch stop layer 741.

Conductive lines 743 may be provided to extend in (e.g., extend through or penetrate) the first etch stop layer 741 and the first interlayer insulating layer 742. The conductive lines 743 may include a conductive material.

A second etch stop layer 751 may be provided on the first interlayer insulating layer 742. A second interlayer insulating layer 752 may be provided on the second etch stop layer 751. A third interlayer insulating layer 753 may be provided on the second interlayer insulating layer 752.

The second etch stop layer 751 may include a third layer 751a on the first interlayer insulating layer 742 and a fourth layer 751b on the third layer 751a. The third layer 751a and the fourth layer 751b may be formed of or include different insulating materials from each other. The second interlayer insulating layer 752 may include an insulating material having an etch selectivity with respect to the second etch stop layer 751. The third interlayer insulating layer 753 may include an insulating material.

A conductive structure 770 may be provided to extend in (e.g., extend through or penetrate) the second etch stop layer 751, the second interlayer insulating layer 752, and the third interlayer insulating layer 753. The conductive structure 770 may be in contact with the conductive lines 743, which are adjacent to each other. A lower portion 771 of the conductive structure 770 may be (at least partially) surrounded (e.g., at least partially enclosed) by the second etch stop layer 751 and the second interlayer insulating layer 752. For example, the second etch stop layer 751 and the second interlayer insulating layer 752 may extend around side surface of the lower portion 771 of the conductive structure 770. An upper portion 772 of the conductive structure 770 may be (at least partially) surrounded (e.g., at least partially enclosed) by the third interlayer insulating layer 753. For example, the third interlayer insulating layer 753 may extend around side surfaces of the upper portion 772 of the conductive structure 770.

The conductive structure 770 may include a barrier layer 774 and a conductive layer 773 on the barrier layer 774. The barrier layer 774 may be in contact with upper (e.g., uppermost) surfaces of the conductive lines 743, a side surface of the second etch stop layer 751, side and upper (e.g., uppermost) surfaces of the second interlayer insulating layer 752, and a side surface of the third interlayer insulating layer 753. The conductive layer 773 may be spaced apart from the upper (e.g., the uppermost) surfaces of the conductive lines 743, the side surface of the second etch stop layer 751, and the side and upper (e.g., uppermost) surfaces of the second interlayer insulating layer 752 by the barrier layer 774. The conductive layer 773 may be in contact with the side surface of the third interlayer insulating layer 753.

In a semiconductor device according to some embodiments of the inventive concept, a length of an upper portion of a conductive structure may be minimized, and this may increase a degree of freedom in designing a semiconductor device.

In a semiconductor device according to some embodiments of the inventive concept, a lower portion of a conductive structure may be formed through a damascene process, and an upper portion of the conductive structure may be formed through an etching process. Accordingly, it may be possible to reduce a difficulty in a process of forming the conductive structure.

While example embodiments of the inventive concept have been particularly shown and described, it will be understood by one of ordinary skill in the art that variations in form and detail may be made therein without departing from the scope of the attached claims.

1. A semiconductor device, comprising:
first conductive lines that are spaced apart from each other; and
a conductive structure that is in contact with upper surfaces of the first conductive lines,
wherein the conductive structure includes a lower portion of the conductive structure and an upper portion of the conductive structure,
wherein the lower portion of the conductive structure is in contact with the upper surfaces of the first conductive lines,
wherein the upper portion of the conductive structure is on the lower portion of the conductive structure,
wherein a width of the lower portion of the conductive structure decreases as a distance between the lower portion of the conductive structure and the upper surfaces of the first conductive lines decreases, and
wherein a width of the upper portion of the conductive structure increases as a distance between the upper portion of the conductive structures and the upper surfaces of the first conductive lines decreases.

2. The semiconductor device of claim 1, wherein the conductive structure includes a barrier layer that is in contact with the upper surfaces of the first conductive lines, and
wherein the conductive structure includes a conductive layer on the barrier layer.

3. The semiconductor device of claim 2, wherein the barrier layer includes a lower portion of the barrier layer and an upper portion of the barrier layer,
wherein the lower portion of the barrier layer is in contact with the upper surfaces of the first conductive lines,
wherein the upper portion of the barrier layer is on the lower portion of the barrier layer, and
wherein a width of the upper portion of the barrier layer increases as a distance between the upper portion of the barrier layer and the upper surfaces of the first conductive lines decreases.

4. The semiconductor device of claim 3, wherein the conductive layer includes a lower portion of the conductive layer and an upper portion of the conductive layer,
wherein the lower portion of the barrier layer extends around the lower portion of the conductive layer,
wherein the upper portion of the conductive layer is on the lower portion of the conductive layer,
wherein an inner side surface of the lower portion of the barrier layer is coplanar with an inner side surface of the upper portion of the barrier layer, and
wherein an outer side surface of the upper portion of the barrier layer is coplanar with an outer side surface of the upper portion of the conductive layer.

5. The semiconductor device of claim 4, further comprising:
a first interlayer insulating layer that extends around the lower portion of the barrier layer and the lower portion of the conductive layer; and
a second interlayer insulating layer that extends around the upper portion of the barrier layer and the upper portion of the conductive layer,
wherein the outer side surface of the upper portion of the barrier layer and the outer side surface of the upper portion of the conductive layer are in contact with the second interlayer insulating layer.

6. The semiconductor device of claim 5, wherein the upper portion of the barrier layer includes a connection surface between the outer side surface of the upper portion of the barrier layer and an outer side surface of the lower portion of the barrier layer, and
wherein the connection surface is in contact with an upper surface of the first interlayer insulating layer.

7. The semiconductor device of claim 5, wherein an angle between the outer side surface of the upper portion of the barrier layer and a lower surface of the second interlayer insulating layer is an obtuse angle, and
wherein an angle between an outer side surface of the lower portion of the barrier layer and an upper surface of the first interlayer insulating layer is an obtuse angle.

8. The semiconductor device of claim 1, further comprising:
a first interlayer insulating layer that extends around the lower portion of the conductive structure; and
a second interlayer insulating layer that extends around the upper portion of the conductive structure,
wherein an angle between an outer side surface of the lower portion of the conductive structure and an upper surface of the first interlayer insulating layer is an obtuse angle, and
wherein an angle between an outer side surface of the upper portion of the conductive structure and a lower surface of the second interlayer insulating layer is an obtuse angle.

9. The semiconductor device of claim 8, further comprising a second conductive line that is in contact with the upper surface of the first interlayer insulating layer,
wherein the second interlayer insulating layer extends around the second conductive line, and
wherein a width of the second conductive line decreases as a distance between the second conductive line and the upper surfaces of the first conductive lines decreases.

10. A semiconductor device, comprising:
a first interlayer insulating layer;
an etch stop layer on the first interlayer insulating layer;
a second interlayer insulating layer on the etch stop layer;
a third interlayer insulating layer on the second interlayer insulating layer;
first conductive lines that are spaced apart from each other and extend in the first interlayer insulating layer; and
a conductive structure that extends in the second interlayer insulating layer, the third interlayer insulating layer, and the etch stop layer and is in contact with upper surfaces of the first conductive lines,
wherein the first interlayer insulating layer includes an intervening portion between the first conductive lines,
wherein the upper surfaces of the first conductive lines are coplanar with an upper surface of the intervening portion, and
wherein a lower surface of the conductive structure is in contact with the upper surfaces of the first conductive lines and the upper surface of the intervening portion.

11. The semiconductor device of claim 10, wherein the lower surface of the conductive structure is substantially flat.

12. The semiconductor device of claim 10, wherein a width of the lower surface of the conductive structure is larger than a sum of widths of the upper surfaces of the first conductive lines and a width of the upper surface of the intervening portion.

13. The semiconductor device of claim 10, wherein the conductive structure includes a lower portion of the conductive structure and an upper portion of the conductive structure,
wherein the second interlayer insulating layer extends around the lower portion of the conductive structure,
wherein the third interlayer insulating layer extends around the upper portion of the conductive structure,
a width of the lower portion of the conductive structure decreases as a distance between the lower portion of the conductive structure and the upper surfaces of the first conductive lines decreases, and
a width of the upper portion of the conductive structure increases as a distance between the upper portion of the conductive structure and the upper surfaces of the first conductive lines decreases.

14. The semiconductor device of claim 10, further comprising:
source/drain patterns that are spaced apart from each other;
a channel structure between the source/drain patterns; and
a gate electrode that overlaps with the channel structure,
wherein the channel structure includes semiconductor patterns overlap with each other,
wherein the gate electrode includes an electrode portion between the semiconductor patterns, and
wherein each of the first conductive lines is electrically connected to a corresponding one of the source/drain patterns or the gate electrode.

15. The semiconductor device of claim 10, wherein the conductive structure includes an upper portion of the conductive structure and a lower portion of the conductive structure,
wherein the upper portion of the conductive structure is in contact with a side surface of the third interlayer insulating layer,
wherein the lower portion of the conductive structure is in contact with a side surface of the second interlayer insulating layer,
wherein the third interlayer insulating layer includes a filling portion that protrudes toward the second interlayer insulating layer and the lower portion of the conductive structure,
wherein the second interlayer insulating layer includes a first curved surface that is in contact with the filling portion, and
wherein the lower portion of the conductive structure includes a second curved surface that is in contact with the filling portion.

16. The semiconductor device of claim 15, wherein the filling portion is between the lower portion of the conductive structure and the second interlayer insulating layer, and
wherein the second curved surface is connected to an outer side surface of the upper portion of the conductive structure.

17. The semiconductor device of claim 10, wherein the conductive structure includes a barrier layer and a conductive layer,
wherein the barrier layer is in contact with the first interlayer insulating layer, the etch stop layer, and the second interlayer insulating layer,
wherein the conductive layer is on the barrier layer,
wherein the conductive layer is spaced apart from the first interlayer insulating layer, the etch stop layer, and the second interlayer insulating layer by the barrier layer, and
wherein the conductive layer is in contact with the upper surfaces of the first conductive lines.

18. The semiconductor device of claim 17, wherein the conductive layer includes penetration portions that extend in the barrier layer, and
wherein the penetration portions are in contact with the upper surfaces of the first conductive lines, respectively.

19. The semiconductor device of claim 10, wherein the conductive structure comprises:
a barrier layer that is in contact with the upper surfaces of the first conductive lines;
a first conductive layer on the barrier layer; and
a second conductive layer that is in contact with an upper surface of the barrier layer and an upper surface of the first conductive layer,
wherein the first conductive layer includes a first conductive material, and the second conductive layer includes a second conductive material that is different from the first conductive material.

20. A semiconductor device, comprising:
a substrate that includes an active pattern;
source/drain patterns on the active pattern;
a channel structure between the source/drain patterns;
a gate electrode that overlaps with the channel structure;
an active contact on each of the source/drain patterns;
a cover insulating layer on the active contact;
a first etch stop layer on the cover insulating layer;
a first interlayer insulating layer on the first etch stop layer;
first conductive lines that are spaced apart from each other and extend in the first etch stop layer and the first interlayer insulating layer;
a second etch stop layer on the first interlayer insulating layer and the first conductive lines;
a second interlayer insulating layer on the second etch stop layer;
a third interlayer insulating layer on the second interlayer insulating layer; and
a conductive structure that is in contact with upper surfaces of the first conductive lines and extends in the second etch stop layer, the second interlayer insulating layer, and the third interlayer insulating layer,
wherein each of the first conductive lines is electrically connected to the active contact or the gate electrode,
wherein the conductive structure incudes a barrier layer and a conductive layer on the barrier layer,
wherein an outer side surface of the barrier layer is in contact with the second interlayer insulating layer, and
wherein an outer side surface of the conductive layer is in contact with the third interlayer insulating layer.

21.-27. (canceled)
